(19) United States
(12) Patent Application Publication
(10) Pub. No.: US 2012/0030936 A1
(43) Pub. Date: Feb. 9, 2012

(54) METHOD FOR PRODUCTION OF A CONDUCTOR BAR FOR THE STATOR OF AN ELECTRICAL MACHINE, IN PARTICULAR OF A GENERATOR, AND AN APPARATUS FOR PRODUCTION OF A CONDUCTOR BAR

(75) Inventor: Hossein Safari Zadeh, Othmarsingen (CH)

(73) Assignee: ALSTOM Technology Ltd, Baden (CH)

(21) Appl. No.: 13/223,769

(22) Filed: Sep. 1, 2011

Related U.S. Application Data
(63) Continuation of application No. PCT/EP2010/052025, filed on Feb. 18, 2010.

(30) Foreign Application Priority Data
Mar. 2, 2009 (CH) 00303/09

(51) Int. Cl. H01R 43/00; H05K 13/04

(52) U.S. Cl. 29/825; 29/729

(57) ABSTRACT

A method is disclosed for production of a conductor bar for the stator of a generator, which conductor bar has a plurality of internal partial conductors which are surrounded externally by insulation which includes an insulating ribbon which is wound around the partial conductors, with the insulating ribbon which is wound around the partial conductors being impregnated with an impregnation fluid. The conductor bar is compressed after the impregnation of the insulating ribbon and at least at times during a curing phase. An apparatus is likewise provided, and can be designed to compress at least an axial section of the conductor bar at least at times during a curing phase of the impregnated insulating ribbon.

### RELATED APPLICATIONS

This application claims priority as a continuation application under 35 U.S.C. §120 to PCT/EP2010/052025, which was filed as an International Application on Feb. 18, 2010 designating the U.S., and which claims priority to Swiss Application 00303/09 filed in Switzerland on Mar. 2, 2009. The entire contents of these applications are hereby incorporated by reference in their entireties.

### FIELD

The present disclosure relates to production of a conductor bar for the stator of an electrical machine, such as a generator, and to compression of insulation of a conductor bar for a stator of an electrical machine.

### BACKGROUND INVENTION

In order to reduce the electrical losses, the stators of generators are formed from a multiplicity of partial conductors which are insulated from one another, so-called Roebel bars. The insulation on the conductor bars includes a surrounding winding with an insulating ribbon which contains mica, or of a mica ribbon, which is impregnated with an impregnation fluid. The impregnation fluid can include a curable synthetic resin, and is used on the one hand for fixing the insulating winding, and on the other hand for improving the insulation, since this can prevent the possibility of moisture absorption.

The insulating ribbon is impregnated with impregnation material, for example in an impregnation bath. The impregnation method can be carried out in an autoclave, in which there is an increased pressure. As soon as it is certain that all the cavities in the insulation wrapping have been filled with the impregnation fluid, the autoclave is once again set to ambient pressure, and the excess impregnation fluid is fed back into a reservoir. The impregnated wrapping on the conductor bar is then cured at ambient pressure.

However, it has been found that conductor bars which have been produced by methods described above can still have small cavities which can lead to a short and/or to an electrical discharge when the conductor bar is subjected to high voltage. Furthermore, the dimensions of the bars are not always uniform, and this can lead to problems in the positioning in the stator core.

### SUMMARY

A method for production of a conductor bar for a stator of an electrical machine, comprising: externally winding a plurality of internal partial conductors of a conductor bar with an insulating ribbon; impregnating the insulating ribbon with an impregnation fluid; and compressing the conductor bar after the impregnation of the insulating ribbon and at least at times during a curing phase.

Apparatus is disclosed for compression of insulation on a conductor bar for a stator of an electrical machine, comprising: a housing for completely surrounding a conductor bar at least in an axial direction of the conductor bar, wherein the conductor bar has a plurality of internal partial conductors, which are surrounded externally by insulation which includes an insulating ribbon which is wound around the partial conductors and is impregnated with an impregnation fluid; and means (e.g., oscillation generator) for application of oscillating pressure forces to the conductor bar.

### BRIEF DESCRIPTION OF THE DRAWINGS

Further advantages and refinements of the disclosure will become evident from the following description and from the attached drawings.

Exemplary embodiments are described in detail in the following text, with reference to the drawings, which schematically illustrate exemplary embodiments.

In the Figures, in each case illustrated schematically:

FIG. 1 shows a method according to a first exemplary embodiment;

FIG. 2 shows an exemplary embodiment of an apparatus as disclosed herein:

FIG. 3 shows an exemplary apparatus according to a second exemplary embodiment;

FIG. 4 shows an enlarged illustration of a part of the exemplary apparatus in FIG. 3;

FIG. 5 shows a front view of an apparatus according to the second exemplary embodiment;

FIG. 6 shows a conductor bar having an apparatus according to a third exemplary embodiment; and

FIG. 7 shows an enlarged illustration of the exemplary apparatus in FIG. 6.

### DETAILED DESCRIPTION

A method is disclosed for production of a conductor bar for the stator of an electrical machine, such as a generator, as well as an apparatus for compression of the insulation on a conductor bar, which make it possible to produce a conductor bar with improved characteristics.

In an exemplary method for production of a conductor bar for the stator of an electrical machine, which conductor bar has a plurality of internal partial conductors which are surrounded externally by insulation which includes a ribbon which is wound around the partial conductors, with the ribbon which is wound around the partial conductors being impregnated with an impregnation fluid, according to an exemplary embodiment, the conductor bar is compressed after the impregnation of the ribbon and at least at times during a curing phase.

It has been found that compression of the impregnated ribbon during a curing phase of the impregnation fluid can lead to a smaller number of cavities in the cured insulation, thus resulting in improved insulation characteristics and improved thermal conductivity.

In an exemplary embodiment, the conductor bar is subjected to a hydrostatic pressure after the impregnation of the ribbon and at least at times during a curing phase. During this process, the pressure can be regulated precisely, and can be exerted uniformly on the insulation.

An exemplary apparatus is disclosed which is designed such that at least an axial section of the conductor bar can be compressed at least at times during a curing phase of the impregnated ribbon.

In an exemplary embodiment, the apparatus surrounds an axial section of the conductor bar and forms a space which is located between the conductor bar and an inner wall of the apparatus, with an inlet being provided for filling the space with a liquid under pressure.

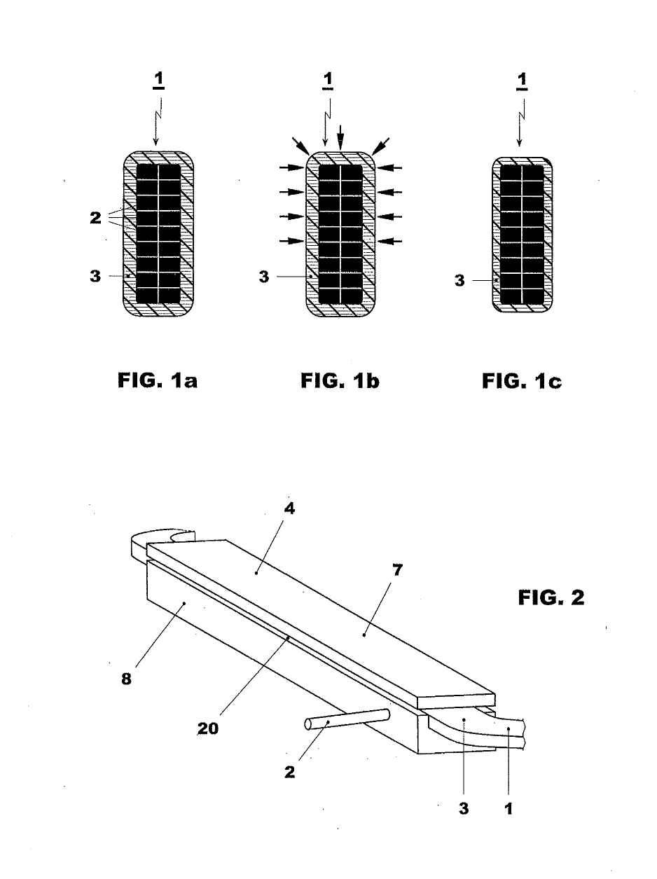

FIG. 1 (a-c) shows a conductor bar 1 for the stator of a generator. The conductor bar 1 has a plurality of internal partial conductors 2. The partial conductors 2 are surrounded externally by insulation 3. The insulation 3 on the conductor bar 1 includes (e.g., consists of) a wrapping with an insulating ribbon which may contain mica. In an exemplary method (FIG. 1a), the insulation 3 is impregnated with an impregnation fluid. The impregnation fluid may include (e.g., consist of) a curable synthetic resin and is used on the one hand for fixing the insulating winding and on the other hand for improving the insulation, by in this way preventing possible moisture absorption. In the exemplary method (FIG. 1b), after the impregnation of the insulation 3 with the impregnation fluid, the conductor bar 1 is compressed at least at times during a curing phase. FIG. 1c shows a conductor bar 1 after curing and compression of the insulation 3.

After the method, the insulation has scarcely any cavities, resulting in improved insulation characteristics and leading to improved thermal conductivity. For a conductor bar with the same cross-sectional area as in known devices, it is either possible to use a greater number of partial conductors 2 or to achieve improved insulation.

FIG. 2 shows an apparatus for compression of the insulation 3 on the conductor bar 1 according to a first exemplary embodiment. The apparatus is designed such that at least an axial section of the conductor bar 1 can be compressed at least at times during a curing phase of the impregnated insulating ribbon. A hydrostatic pressure can be used for compression. In the embodiment in FIG. 2, a housing 4 surrounds an axial section of the conductor bar 1 and forms a space 20 which is located between the conductor bar 1 and an inner wall of the housing. The housing 4 is formed by an upper part 7 and a lower part 8, which together surround the conductor bar 1 over its entire circumference, as can be seen from FIG. 2. The upper part 7 and the lower part 8 are connected to one another, forming a seal.

The axial length of the apparatus can, for example, be matched to the axial length of a straight section of the conductor bar 1. The axial ends of the upper and lower parts 7, 8 are sealed to the conductor bar 1 by means such as a seal or other sealing device. An inlet 22 is provided for filling the space 20 with a liquid under pressure. In this case, a high-viscosity liquid can for example, be used, such as oil or asphalt (Isotenax). The hydrostatic pressure exerts a uniform pressure, which can be regulated, on the insulation. In an exemplary embodiment, the apparatus 4 can be designed to exert a pressure of at least 50 bar to 350 bar (or lesser or greater), preferably, for example, of 300 bar, on the insulation 3. In a further exemplary embodiment, the apparatus is designed to exert an increased pressure at an increased temperature.

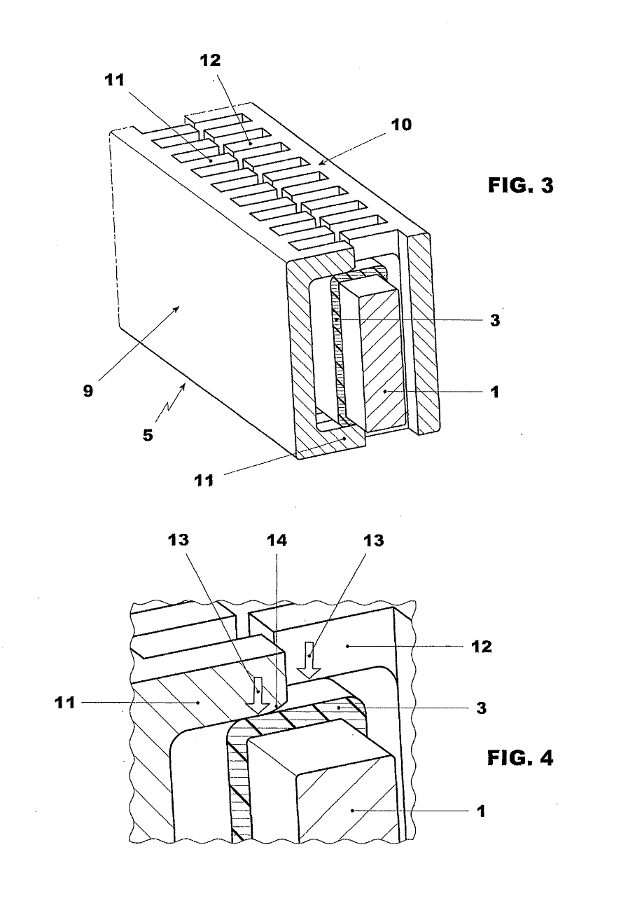

FIGS. 3 to 5 show an exemplary apparatus for compression of the insulation 3 on the conductor bar 1 according to a second exemplary embodiment. The apparatus is a pressing tool.

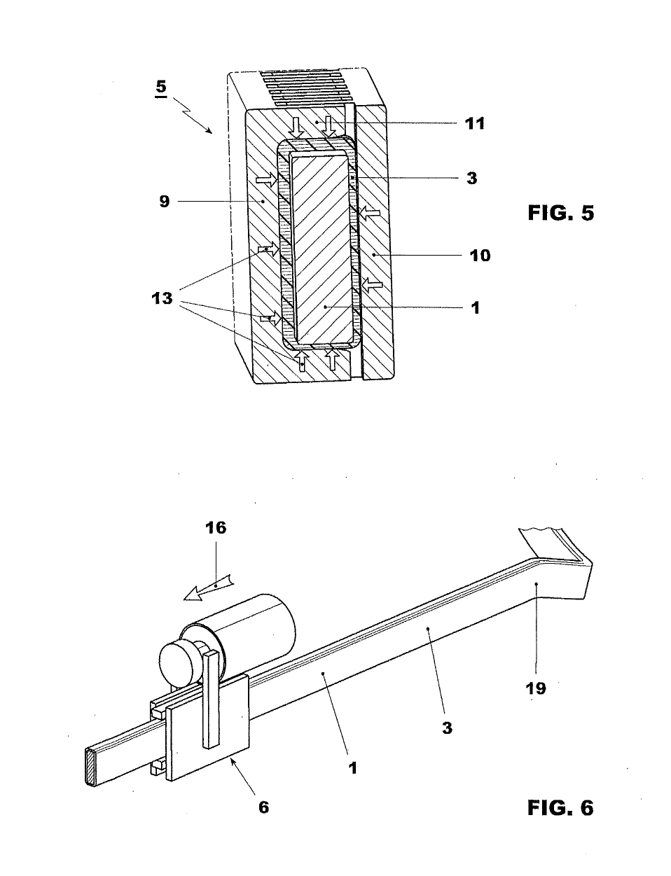

The apparatus has a housing which includes (e.g., consists of) two parts 9, 10 and which, when pressed together (see FIG. 5), circumferentially surrounds an axial section of the conductor bar 1. The two parts 9, 10 are C-shaped with free ends 11, 12 formed like combs. The free ends 11, 12 of the parts 9 and 10 are arranged offset with respect to one another such that one free end 11 or 12 of the one of the parts 9 or 10 in each case engages, like a comb, in a respective gap in the other part 11 or 12. The pressure forces which act compress the insulation 3, as illustrated by the arrows 13 in FIGS. 4 and 5. The two parts 9, 10 are pressed together with high pressure, in order to uniformly compress the insulation 3 at least at times during the curing of the impregnation fluid. The free ends 11, 12 of the C-shaped parts 9, 10 expediently have rounded or profiled surfaces 14 which allow the ends 11, 12 to slide over the insulation 3, and at the same time allow the insulation 3 to be compressed. The axial length of the apparatus 5 can be chosen such that even a curved area of the conductor bar can be compressed by the apparatus 5. The apparatus 5 can correspondingly compress the insulation 3 on the conductor bar in sections. The two parts 9, 10 are pressed together by means for pressing, such as a suitable pressing tool.

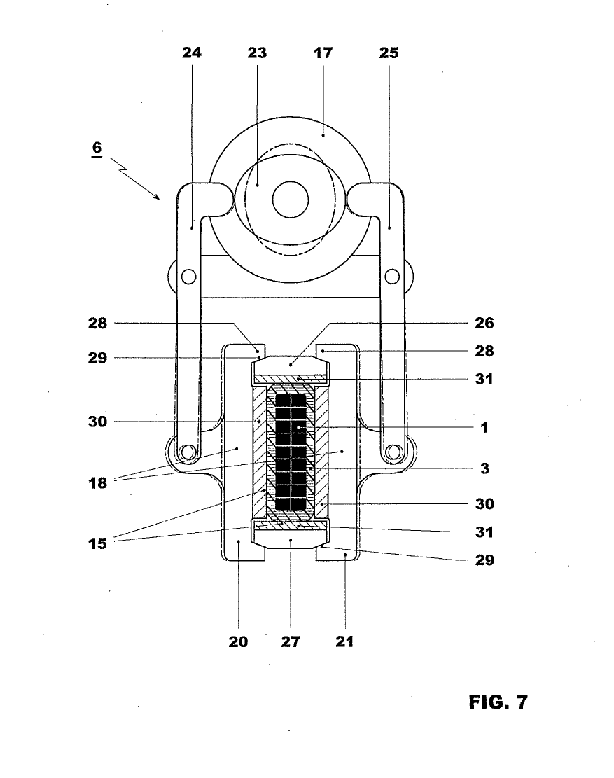

FIGS. 6 and 7 show an apparatus 6 for compression of the insulation 3 on a conductor bar 1 according to a third exemplary embodiment. The apparatus 6 comprises a multi-part housing 18 which surrounds the conductor bar 1 and has pressing surfaces 15 which act on the insulation 3 on the conductor bar 1. The pressing surfaces 15 each circumferentially surround an axial section of the conductor bar 1. The pressing surfaces 15 of the apparatus 6 are for example, formed with a conical area in the axial direction 16 of the conductor bar 1. In this case, a conductor bar input side of the apparatus 6 has a larger cross section than a section of the pressing surfaces which follows this. An exemplary aim of this is to ensure that the apparatus 6 slides better over the insulation 3 on the conductor bar 1. The conical area can be formed at both ends of the apparatus 6, in order to allow the apparatus 6 to be moved along the conductor bar 1 in both directions.

The apparatus 6 may be formed from two housing shells 20 and 21. Each of these housing shells 20 and 21 is able to apply a predetermined contact pressure to the conductor insulation 3 to be compressed, and to carry out oscillations at an adjustable frequency. For this purpose, the housing shells 20 and 21 are linked to the oscillation generator 17. Oscillations can be applied to them hydraulically, pneumatically or mechanically. FIG. 7 shows a mechanical oscillation generator 17, schematically, based on a rotating non-round disk 23. Two levers 24 and 25 follow the surface of the disk 23 and convert its contour fluctuations to tilting movements, which are transmitted to the housing shells 20 and 21. The housing shells 20, 21 carry out an up-and-down movement at right angles to the pressing surfaces 15, depending on the contour and the rotation speed of the disk 17. Oscillations are, for example, always applied in opposite senses to the housing shells 20 and 21 by the disk 17 being symmetrical and by the levers 24 and 25 being arranged symmetrically. The use of mutually opposite forces serves to stabilize the system and to avoid unbalances.

The two housing shells 20, 21 bound spacers 26, 27. Their function is on the one hand to provide pressing surfaces 15 for the narrow faces of the conductor bar 1. At the same time, they form a stop for the housing shells 20 and 21 and are therefore used to ensure dimensional stability of the insultated conductor bar 1, 3. As can be seen, the spacers 26, 27 are partially surrounded externally by projections 28 from the housing shells 20, 21. The common contact surfaces 29 have an inclination between greater than 0° and less than 90°, which is not self-locking. The pressure forces and oscillations which are applied to the housing shells 20 and 21 are therefore transmitted to the spacers 26 and 27, and are introduced via their pressing surfaces 15 into the narrow faces of the conductor bar 1.

The oscillation generator 17 leads to oscillation of the pressing surfaces 15, with the insulation 3 on the conductor bar 1 being compressed by the pressure forces and oscillations applied by the pressing surfaces 15. The energy introduced by the oscillations can also lead to heating of the insulation 3, which can iniate the curing phase of the insulating fluid. Frequencies in an exemplary range 5 Hz to 50 Hz have been found to be advantageous.

Apart from one or two conical end sections of the apparatus 6, the pressing surfaces 15 can be matched to the contour and the dimensions of the desired end profile of the insulated conductor bar 1. According to an exemplary embodiment, replaceable inserts 30, 31 can be fitted in the cavity which is surrounded by the housing 20, 21, 26, 27. A plurality of inserts 30, 31 can kept available as appropriate for the housing (20, 21, 26, 27) and their contour and dimensions are matched to the requirements of conductor bars 1 of different design. Conductor bars 1 of different size can therefore be handled using the same apparatus 6, or a conductor bar 1 can be compressed in a plurality of successive compression processes, in which case the molding cavity in the compression apparatus 6 can be appropriately adapted between two compression processes, by replacement of the inserts 30, 31. The axial length of the apparatus 6 can be chosen such that even a curved area 19 of the conductor bar 1 can be handled by means of the compression apparatus 6.

In order to compress the insulation 3 on a conductor bar 1, the apparatus 6 can be placed on the conductor bar 1. The oscillation generator 17 is then switched on, and the apparatus 6 is moved along the conductor bar 1. During this process, the conductor bar 1 can be fixed, such that it cannot move.

The above description of the exemplary embodiments is intended only for illustrative purposes, and not for the purpose of restricting the invention. Particularly with respect to some of the preferred exemplary embodiments a person skilled in the art will see that various changes and modifications can be made in the form of details without departing from the essence and scope of the invention. The present disclosure is accordingly not intended to be restrictive. Instead, the disclosure is intended to illustrate the scope of the invention, as described in the following claims.

Thus, the scope of the invention is indicated by the appended claims rather than the foregoing description and all changes that come within the meaning and range and equivalence thereof are intended to be embraced therein.

### LIST OF REFERENCE SYMBOLS

1 Conductor bar
2 Partial conductor
3 Insulation
4 Housing
5 Housing
6 Apparatus
7 Upper part
8 Lower part
9 Part of housing 5
10 Part of housing 5
11 Free ends
12 Free ends
13 Arrow
14 Rounded or profiled surfaces
15 Pressing surface
16 Axial direction
17 Oscillation generator
18
19 Curved area of the conductor bar 1
20 Housing shell
21 Housing shell
22 Fluid supply
23 Rotating disk
24 Lever arm
25 Lever arm
26 Spacer
27 Spacer
28 Projections on 20 and 21
29 Contact surface
30 Inserts
31 Inserts

1. A method for production of a conductor bar for a stator of an electrical machine, comprising:
externally winding a plurality of internal partial conductors of a conductor bar with an insulating ribbon;
impregnating the insulating ribbon with an impregnation fluid; and
compressing the conductor bar after the impregnation of the insulating ribbon and at least at times during a curing phase.

2. The method as claimed in claim 1, comprising:
applying oscillating pressure forces to the conductor bar during compression.

3. The method as claimed in claim 1, comprising:
subjecting the conductor bar to a hydrostatic pressure after the impregnation of the insulating ribbon and at least at times during a curing phase.

4. The method as claimed in claim 1, wherein the hydrostatic pressure is applied by a viscous liquid.

5. The method as claimed in claim 1, comprising:
subjecting the conductor bar to increased pressure after the impregnation of the insulating ribbon and at least at times during a curing phase at an increased temperature.

6. The method as claimed in claim 5, wherein the increased pressure is at least 50 bar.

7. The method as claimed in claim 5, wherein the increased pressure is at most 350 bar.

8. The method as claimed in claim 2, comprising:
subjecting the conductor bar to oscillating pressure forces in places along its axial length in successive steps.

9. Apparatus for compression of insulation on a conductor bar for a stator of an electrical machine, comprising:
a housing for completely surrounding a conductor bar at least in an axial direction of the conductor bar, wherein the conductor bar has a plurality of internal partial conductors, which are surrounded externally by insulation which includes an insulating ribbon which is wound around the partial conductors and is impregnated with an impregnation fluid; and
means for application of osciallating pressure forces to the conductor bar.

10. The apparatus as claimed in claim 9, comprising:
means for application of a hydrostatic pressure to the conductor bar.

11. The apparatus as claimed in claim 10, wherein the housing surrounds an axial section of the conductor bar to form a space between the conductor bar and an inner wall of the housing, with an inlet being provided in order to fill the space with a liquid under pressure.

12. The apparatus as claimed in claim 11, wherein the housing comprises:
at least one upper part and at least one lower part, for together surrounding the conductor bar, with axial ends of the at least one upper part and of the at least one lower part surrounding the conductor bar, forming a seal.

13. The apparatus as claimed in claim 10, wherein the housing comprises:
two parts which are arranged such that they can move with respect to one another, each of the parts having free ends which are arranged as a comb to engage in one another in a closed state, the housing being configured to circumferentially surround an axial section of the conductor bar in the closed state.

14. The apparatus as claimed in claim 13, wherein the two parts are C-shaped such that, at least in the closed state, the free ends of one of the C-shaped parts engage like a comb in the free ends of the other of the C-shaped parts.

15. The apparatus as claimed in claim 9, comprising:
at least two housing shells which are separated from one another;
at least two spacers between the housing shells, with the housing shells and the spacers surrounding a cavity for an axial section of the conductor bar;
an oscillation generator, for acting on the at least two housing shells; and
pressing surfaces, by which the housing shells and the spacers will act on insulation on the conductor bar.

16. The apparatus as claimed in claim 15, wherein the housing shells have projections which clasp the spacers.

17. The apparatus as claimed in claim 16, wherein contact surfaces run inclined between the projections and the spacers, such that the projections taper toward their ends.

18. The apparatus as claimed in claim 15, comprising:
replaceable inserts for inserting into the housing shells and the spacers.

19. Apparatus for compression of insulation on a conductor bar for a stator of an electrical machine, comprising:
a housing for completely surrounding a conductor bar at least in an axial direction of the conductor bar, wherein the conductor bar has a plurality of internal partial conductors, which are surrounded externally by insulation which includes an insulating ribbon which is wound around the partial conductors and is impregnated with an impregnation fluid; and
an oscillation generator for application of oscillating pressure forces to the conductor bar.
